(19) United States
(12) Patent Application Publication
(10) Pub. No.: US 2013/0206211 A1
(43) Pub. Date: Aug. 15, 2013

(54) Phosphors-Based Solar Wavelength-Converters

(71) Applicant: Intematix Corporation, (US)

(72) Inventors: Yi-Qun Li, Danville, CA (US); Wei Shan, Fremont, CA (US); Shifan Cheng, Dublin, CA (US); Mike Ko, Fremont, CA (US)

(73) Assignee: Intematix Corporation, Fremont, CA (US)

(21) Appl. No.: 13/804,477

(22) Filed: Mar. 14, 2013

Related U.S. Application Data
(63) Continuation of application No. 11/731,802, filed on Mar. 30, 2007.
(60) Provisional application No. 60/787,930, filed on Mar. 31, 2006.

(51) Int. Cl. H01L 31/055

(52) U.S. Cl. CPC H01L 31/055
USPC 136/247; 136/257

(57) ABSTRACT

A solar wavelength-converter for converting higher energy shorter wavelength solar radiation to lower energy longer wavelength light, comprises: a transparent matrix having particles of at least one inorganic phosphor embedded in it in which the at least one phosphor is configured to absorb light of wavelengths between about 300 nm and about 480 nm and convert it to light with a wavelength greater than about 500 nm. The at least one phosphor can comprise: a YAG:Ce phosphor; a silicate-based phosphor of a form M₂Sia₄:Eu²⁺; a silicate-based phosphor of a form M₃SiO₅:Eu₂₊, where M is a divalent cation in the silicate-based phosphors or combinations thereof. The at least one phosphor can comprise particles of a size that is substantially transparent to solar radiation having a wavelength greater than about 460 nm.

### CROSS REFERENCE TO RELATED APPLICATIONS

This application is a Continuation of application Ser. No. 11/731,802, filed Mar. 30, 2007, which claims the benefit of priority to Provisional Application No. 60/787,930, filed Mar. 31, 2006, the content of each of which is hereby incorporated by reference in its entirety.

### BACKGROUND OF THE INVENTION

1. Field of the Invention

Embodiments of the present invention are directed in general to phosphor-based solar wavelength-converters (also known as wavelength-shifters) for reshaping the spectral distribution of the photon flux of sunlight. In particular, although not exclusively, embodiments concern solar wavelength-converters that may be incorporated with, or placed on or adjacent to a photovoltaic cell, such as a solar cell, for enhancing the efficiency of a solar cell.

2. Description of the Related Art

Today's solar cell and/or photovoltaic devices suffer from an inherent inefficiency: they typically are able to convert only a portion of the solar spectrum to electricity. This portion of the spectrum is the longer wavelength, lower energy portion of the spectrum, which means that the shorter wavelength, higher energy portion is wasted. To improve the conversion efficiency of a semiconductor solar cell, thereby increasing the power output of the solar cell, a number of schemes have been proposed in past decades. These schemes have attempted to make “better use” of the solar spectrum, and have in general been referred to as “third-generation” photovoltaic devices (first and second-generation devices will be discussed later).

Up and down wavelength-conversion of photon energy are among the schemes most frequently cited. In one type of down conversion scheme, a higher-energy photon is “converted” to two lower-energy photons, in an attempt to reduce excess energy losses, and to make better use of the short wavelength range of the solar spectrum. In contrast, past up conversion schemes have “converted” two lower-energy photons to one higher-energy photon for utilizing the unabsorbed parts of the spectrum. These conversions are a second-order quantum process involving three photons, however, and therefore their transition probabilities are fairly limited under conditions of normal solar irradiation.

In the 1970s, it was suggested that luminescent concentrators could be attached to a solar cell to effect spectral down conversion. In some of these concentrators, organic dyes were used to absorb incident light, and to reemit energy at a red-shifted wavelength. Internal reflection ensured the collection of substantially all of the reemitted light by the underlying solar cells in the device. It was suggested that a number of different organic dye molecules were appropriate, since the reemitted light could be matched for optimal conversion by different solar cell designs. This is similar conceptually to the use of a stack of multiple solar cells, each solar cell in the stack sensitive to a different part of the solar spectrum.

Though enhanced efficiencies were predicted by theory, the desired results were not actually obtained in practice as a result of the organic dye molecules' inability to meet certain stringent requirements. These requirements included sufficient quantum efficiency and stability. Another problem lay in the transparency (or rather lack thereof) of the matrix materials in which the dye molecules were dispersed.

It is known in the art that the efficiency of a solar cell or photovoltaic device may be enhanced by optically coupling a wavelength converter to the solar or photovoltaic cell, the wavelength converter capable of shifting higher energy light to a lower energy form, the latter being more suitable for the typical solar cell to convert into electricity. Such wavelength converters are described as “wavelength-shifting devices” in U.S. Pat. No. 4,891,075 to Dakubu. As taught in that patent, wavelength shifting devices allow utilization of energy from the energy-rich portion of the solar spectrum, a region which was previously “unavailable” to a photovoltaic cell.

The wavelength-shifting device of U.S. Pat. No. 4,891,075 was a dihydropyridine condensation product which was chelated to a lanthanide ion in a polymer. When such a wavelength-shifting device was coupled to a photovoltaic cell, the condensation product absorbed “a significant level of energy” and transferred the energy the lanthanide ion. The lanthanide ion then emitted or fluoresced light at a longer wavelength (lower energy). Typically, photovoltaic devices are only able to utilize energy (i.e., be able to convert the light to electricity) at these longer wavelengths, and so by coupling their chelated condensation product to a solar cell, energy from the shorter wavelength portion of the solar spectrum could be utilized as well.

In fact, the majority of past wavelength-shifting devices have been organic in nature, organic dyes being possibly the most common material encountered. Thus, methods and techniques are still needed in the art that can make better use of the solar spectrum; in general, this means making use of regions of the spectrum that would otherwise have been “wasted.” More specifically, what is needed in the art are methods and techniques for spectrally shifting regions of the solar spectrum to wavelengths that are better matched to the spectral response of the solar cells being used to generate electricity, while simultaneously providing materials in wavelength-converting systems with enhanced stability and transparency. By inexpensively capturing that portion of the solar spectrum in the short wavelength region that would otherwise not be normally be utilized by a solar or photovoltaic cell conversion efficiency of existing silicon-based solar/photovoltaic cells may be substantially enhanced. Needless to say, increasing the efficiency of the solar device effectively reduces the cost per watt of solar electricity generated.

### SUMMARY OF THE INVENTION

The present embodiments are directed to phosphor-based solar wavelength-shifters (also known as wavelength-converters) for reshaping the spectral distribution of the photon flux of sunlight by shifting higher energy sunlight to a lower energy form. The absorption of the phosphor may range from about 300 to 480 nm. Advantageously, the phosphor component of the wavelength-converter may be in the form of nano-particles embedded in a transparent matrix for reducing scattering losses of light with wavelength longer than about 460 nm.

According to one embodiment a solar wavelength-converter for converting higher energy shorter wavelength solar light to lower energy longer wavelength light, comprises: a transparent matrix having particles of at least one inorganic phosphor embedded in it wherein the at least one phosphor is configured to absorb solar radiation of wavelengths between about 300 nm and about 480 nm and convert it to light with a wavelength greater than about 500 nm.

To reduce scattering losses of light that in not being converted by the wavelength-converter, the at least one phosphor comprises particles of a size that is substantially transparent to solar radiation having a wavelength greater than about 460 nm. Preferably, the at least one phosphor comprises nano-particles in which at least some of the at least one phosphor particles have a dimension of about 100 nm or less.

The transparent matrix can comprise a polymeric material such as a silicone gel.

Advantageously the at least one phosphor comprises a crystalline material doped with a rare-earth element including for example a YAG:Ce phosphor; a silicate-based phosphor of a form M₂SiO₄:Eu²⁺ or a silicate-based phosphor of a form M₃SiO₅:Eu₂+, where M is a divalent cation silicate-based phosphors.

In one embodiment the at least one phosphor has a composition (Ba_{1-x-y}SrₓMg_{y})_{z}SiO_{2+z}:Eu²⁺, where 0≦x≦1; 0≦y≦1; and z is any value between 1.5 and 2.5, both inclusive. In another embodiment the at least one phosphor has a composition (Ba_{1-x-y}SrₓMg_{y})_{z}SiO_{2+z}:Eu²⁺, where 0≦x≦1; 0≦y≦1; and z is any value between 2.5 and 3.5, both inclusive. Examples of such phosphors includes:

Sr_{0.925}Ba_{1.025}Mg_{0.05}Eu_{0.06}Si_{1.03}O₄Cl_{0.12};

Sr_{1.40}Ba_{0.55}Mg_{0.05}Eu_{0.06}Si_{1.03}O₄Cl_{0.12};

Sr_{0.6}Ba_{0.35}Mg_{0.05}Eu_{0.06}O₄Cl_{0.12;}

Sr_{1.725}Ba_{0.225}Mg_{0.05}Eu_{0.06}Si_{1.03}O₄Cl_{0.12};

Sr_{1.725}Ba_{0.15}Mg_{0.05}Eu_{0.06}Si_{1.03}O₄Cl_{0.12};

Sr₃Eu_{0.06}Si_{1.02}O₅F_{0.18};

Sr_{2.94}Ba_{0.06}Eu_{0.06}Si_{1.02}O₅F_{0.18};

(Sr_{0.9}Ba_{0.1})_{2.76}Eu_{0.06}Si_{1.02}O₅F_{0.18}; and combinations thereof.

According to a further embodiment of the invention a solar wavelength-converter for converting higher energy shorter wavelength solar light to lower energy longer wavelength light, comprises: a transparent matrix having particles of at least one inorganic phosphor embedded in it wherein the at least one phosphor comprises: a YAG:Ce phosphor; a silicate-based phosphor of a form M₂SiO₄:Eu²⁺; a silicate-based phosphor of a form M₃SiO₅:Eu₂+, where M is a divalent cation in the silicate-based phosphors; or combinations thereof. The at least one phosphor can comprise a composition (Ba_{1-x-y}SrₓMg_{y})_{z}SiO_{2+z}:Eu²⁺, where 0≦x≦1; 0≦y≦1; and z is any value between 1.5 and 2.5, both inclusive. Alternatively the at least one phosphor can comprise a composition (Ba_{1-x-y}SrₓMg_{y})_{z}SiO_{2+z}:Eu²⁺, where 0≦x≦1; 0≦y≦1; and z is any value between 2.5 and 3.5, both inclusive. In other embodiments the at least one phosphor has a composition (Ba_{1-x-y}SrₓMg_{y})_{z}SiO_{2+z}:Euₓ²⁺, where 0.001≦x≦0.2; 0.001≦y≦0.2; and z is any value between 1.5 and 2.5, inclusive.

Preferably the at least one phosphor is configured to absorb light of wavelengths between about 300 nm and about 480 nm and convert it to light with a wavelength greater than about 500 nm. To reduce scattering losses of light that in not being converted by the wavelength-converter, the at least one phosphor comprises particles of a size that is substantially transparent to solar radiation having a wavelength greater than about 460 nm. Preferably, the at least one phosphor comprises nano-particles in which at least some of the at least one phosphor particles have a dimension of about 100 nm or less.

According to a further aspect of the invention a photovoltaic device with enhanced conversion efficiency, comprises: a solar cell for converting solar radiation into electrical energy; and a solar wavelength-converter in accordance with embodiments of the invention that is configured to emit converted light with a wavelength greater than about 500 nm onto the solar cell.

### BRIEF DESCRIPTION OF THE DRAWINGS

FIG. 1 shows the spectral distribution of photon flux at AM1.5G irradiance, and the internal spectral response of a normal silicon p-n junction photovoltaic cell;

FIG. 2 shows a comparison between the converted solar energy for a silicon solar cell, the calculation based on the Shockley-Queisser model taking into account the both situations where spectral response was and was not considered;

FIG. 3 is an excitation curve of one of the inventors' silicate-based phosphors, which phosphor may be used in nano-particle form as a wavelength converter, the graph showing that the absorption of the phosphor may range from about 300 to 480 nm in one embodiment, and about 280 to 460 in another embodiment:

FIG. 4 shows the quantum efficiency curve of a typical poly-crystalline silicon solar cell;

FIG. 5 shows the emission spectra of exemplary silicate-based phosphors that may be used as wavelength-converters, optionally in nano-particle form;

FIG. 6 is a graph of photon flux to a solar cell in the present of a 565 nm phosphor, assuming a quantum efficiency of about 0.8 to 0.9; and

FIG. 7 shows the results of converted solar energy using a 565 nm phosphor spectral shifter under AM1.5G solar irradiance; included for comparison is the spectral irradiance without the spectral shifting wavelength converter.

### DETAILED DESCRIPTION OF THE INVENTION

Embodiments of the present invention are directed in general to the field of photovoltaic (PV) technologies that convert solar energy directly into electrical energy. More specifically, the field of the invention is directed to a phosphor-based wavelength-shifter (also known as wavelength-converter) that may be incorporated with, or placed on or adjacent to a photovoltaic cell for reshaping the spectral distribution of the photon flux incident to the solar cell. The enhanced match between the incident photon flux and the spectral response of the photovoltaic cell increases the output power of the solar device. Especially provided by the present embodiments are wavelength-converters comprising nano-particles of phosphor, where the nano-particles may be embedded in a transparent matrix.

The vast majority of solar panels today are made of silicon single-junction solar cells. These devices are called first generation, and highly stable solar cells. Unfortunately, it is inherently expensive to make first generation solar cells because silicon is an indirect band gap semiconductor, and as such a thick layer is required to absorb substantially all of the solar irradiation impinging on it. Thick layers consume large volumes of raw material. In addition, the cost of materials processing necessary to fabricate the devices, i.e. the thermal budget, is very high, making first generation solar cells even more expensive.

The conversion efficiency of solar energy to electricity in this type of solar cells is fairly small, approximately 15 percent at standard temperature conditions. Most of the solar conversion is lost as heat. A more recent and still uncommon alternative to manipulating large silicon wafers involves constructing thin-film solar cells with the potential to produce solar energy at a much-reduced cost. These thin-film based solar cells are called second generation, and they are targeted to be lest costly than first generation devices, with little or no sacrifice in conversion efficiency. However, silicon-based thin-film cells have difficulty absorbing solar irradiation, and thus suffer from low efficiencies as well. The so-called Carnot limit on the conversion of sunlight to electricity is about 95 percent, to be contrasted with an upper limit of about 33 percent for standard single-junction solar cells. This suggests that the performance of solar cells can be much improved in terms of conversion efficiency if novel concepts are used to develop more advanced solar technologies, thereby producing high-efficiency and low-cost solar and photovoltaic devices.

It may be beneficial at this stage of the disclosure to touch on the theory of spectral loses suffered by a single-junction solar or photovoltaic cell. The fundamental spectral losses in a single-junction solar cell, fabricated from a semiconducting material such as silicon, result from a spectral mismatch between the incident solar radiation and the absorption characteristics of the semiconductor. See, for example, M. A. Green in Solar Cells: Operating Principles, Technology and Systems Application (Prentice Hall, Englewood Cliffs, N.J., 1982). Due to the fact that semiconductors have discrete band structures, there are essentially three kinds of spectral losses for a solar cell using a given material: 1) sub-bandgap loss, 2) thermalization loss, and 3) spectral response loss. These types of losses will be addressed in turn.

The first type of spectral loss may be called sub-bandgap loss. Absent trap states, typically only photons with energies equal to or greater than the material's band gap will be absorbed, and therefore contribute to the electrical output of a photovoltaic (PV) device. Photons with energy Eₚₕ smaller than the band gap E_{g} of the material that are not absorbed may be transmitted through the solar cell, and these of course do not contribute to the electrical output of the device. Such sub-bandgap losses are one of the main loss mechanisms that limit the efficiency of conventional single-junction solar cells.

The second type of spectral loss may be called thermalization loss. Photons with energy Eₚₕ larger than the band gap may be absorbed, but the excess energy Eₚₕ-E_{g} is not used effectively due to thermalization of the electrons. This is a process that emits phonons (heat) rather than photons.

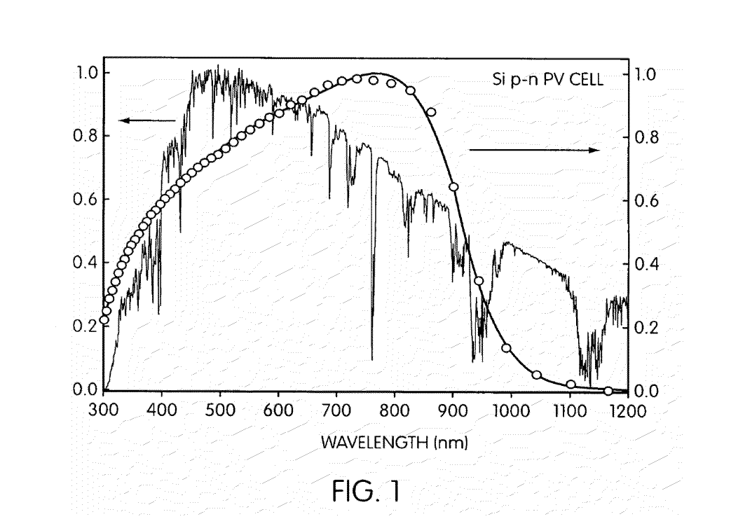

The third type of loss may be called spectral response loss. The sensitivity of a solar cell to the different wavelength ranges of solar radiation varies depending on the technology of the solar cell, including the particular material used. In other words, the number of carriers collected per incident photon at each wavelength is a function of wavelength, a parameter generally described as “quantum efficiency.” As shown in FIG. 1, the spectral response of a conventional silicon p-n photovoltaic cell does not particularly well match the spectral distribution of sunlight.

In general, the shorter the wavelength of the incident light the lower the photocurrent generated. This is because electrons generated by short-wavelength incident light have a higher concentration at the vicinity of the surface of the absorbing material, therefore generating a higher probability of loss before such electrons can diffuse to the p-n junction region. The higher probability of loss is due to various recombination mechanisms that may take place with shorter wavelength (higher energy) photons, such as surface recombination, a fate not as likely to be suffered by longer wavelength photons.

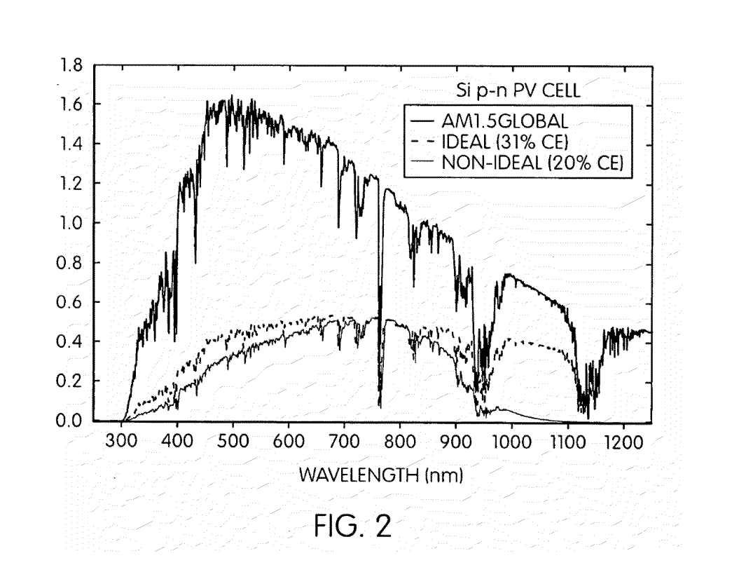

FIG. 2 shows a comparison between the converted solar energy for a silicon solar cell, the calculation based on the Shockley-Queisser model taking into account both situations where spectral response is, and is not being considered. The spectral irradiance of AM1.5G (shown in FIG. 2 as a grey area) was used as a reference in the calculation. The model shows a conversion efficiency of about 31 percent under ideal conditions; i.e., the process is wavelength-independent, and solar cell is exhibiting a 100 percent internal quantum efficiency. The model then predicts a decrease in conversion efficiency to about 21 percent when an actual, wavelength-dependent spectral response is taken into account. Spectral response loss can be as large as about 50 percent when additional factors are taken into consideration, such as the type of material from which the device is constructed, and the structural configuration of the device.

### Quantifying “High” and “Low” Energy Light in Relation to the Solar Spectrum

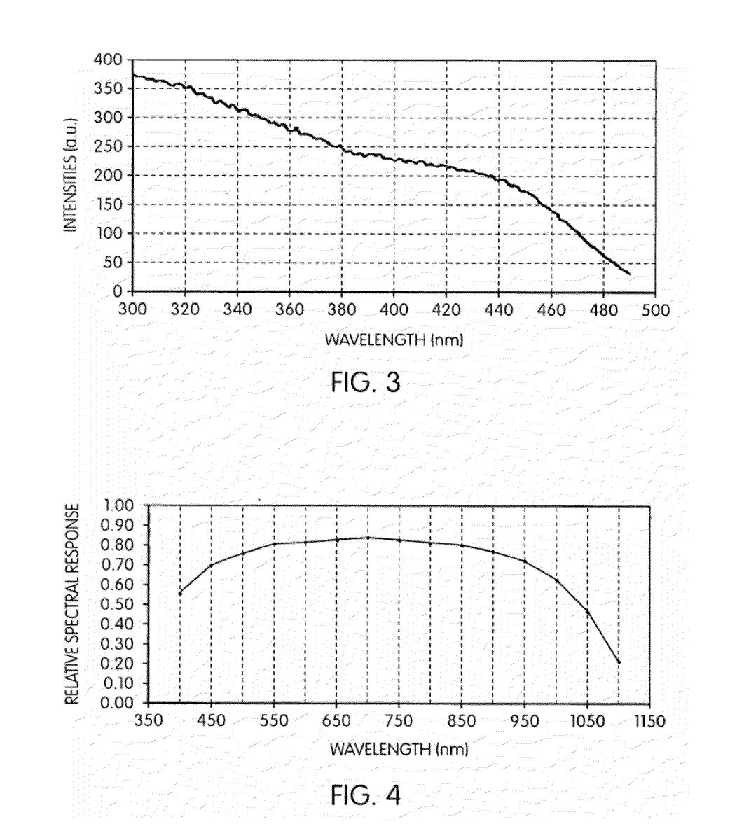

According to embodiments of the present invention, the wavelength-converting material(s) are substantially transparent to solar radiation having a wavelength greater than about 460 nm, thus minimizing competitive absorption. Radiation below about 460 nm is absorbed by the wavelength-converting material(s), and this absorbed, shorter wavelength light (higher energy light) is converted to lower energy, Exemplary delineations between higher and lower energy light (shorter and longer wavelengths, respectively) may be appreciated after inspecting the data of FIGS. 3 and 4, generated with the use of a phosphor (or phosphor blend, or phosphor composition) as the wavelength-converting material. FIG. 3 is an excitation curve of an exemplary phosphor composition. It will be understood by one skilled in the art that an “excitation spectrum” is actually an emission spectrum, where the intensity of the light emitted is measured as a function of the wavelength of the excitation radiation. In this case, the excitation radiation comes from the sun. A particular wavelength is chosen at which to measure the light emitted from the phosphor (typically the wavelength at which peak emission occurs for that particular phosphor), and it is the wavelength of the radiation incoming to the phosphor/wavelength-converter that is scanned.

The data of FIG. 3 illustrates that absorption of a phosphor can range from 300 to 480 nm, although the efficiency starts to drop off rapidly as the excitation wavelength is increased to values greater than about 460 nm. Though not shown, the present inventors have found that by varying the materials preparation process, one may tune the absorption band of the wavelength-converter to different portions of the solar spectrum; these may actually range from the ultraviolet (UV) to the visible. It is contemplated that wavelength down to 280 nm may be effectively converted as well, such that the wavelengths of light considered to be “high energy,” and appropriate for conversion to lower energy light for use by the photovoltaic device, may be thought of as about 280 to about 460 nm, both inclusive.

“Lower energy light,” as this term relates to the solar spectrum, may be defined by the absorption characteristics of a particular photovoltaic device (where the device prefers to absorb), and by the wavelengths of the photoluminescent light emitted by the wavelength-converter; that is to say, light that has been conditioned for use by the photovoltaic cell. Ideally, the optimal performance of a single-junction solar cell is achieved when it is being irradiated by monochromatic light having a wavelength λₒₚₜ=1240/E_{g}, where E_{g} is the fundamental band-gap energy of the material from which the solar cell has been fabricated.

This wavelength of incident light is optimum because there is substantially no loss of energy from the photoexcited carriers being electrically conducted within the solar cell material. Theoretically speaking, the optimum wavelength λₒₚₜ=1100 nm (with E_{g}=1.1 eV) when the material of the solar cell is crystalline silicon, and λₒₚₜ=700 nm (with E_{g}=1.77 eV) for hydrogenated amorphous silicon (denoted by the nomenclature a-Si:H). In reality, single-junction solar cells perform optimally when exposed to monochromatic light having a wavelength λₒₚₜ=1240/Eₒₚₜ, where Eₒₚₜ is an energy lying somewhere between the maximum spectral response of the solar cell and its band-gap energy E_{g}.

That the optimum energy lies between these two values is due in part to the spectral absorption properties of the solar cell material. It is also dependent on a balancing act between loss of excess energy (which ideally one of skill in the art would want to minimize) and internal quantum efficiency (which one would want to maximize). For instance, as amorphous silicon solar cells only contain a thin absorber layer, the actual optimum spectrum response is at about 550 nm.

It has been demonstrated that the conversion efficiency of these types of solar cells measured at an incident monochromatic light of 550 nm can be as high as 20 percent, in contrast to the observed air mass 1.5 global (AM1.5G) efficiency of 10 percent. Therefore, conversion of the full solar spectrum to quasi-monochromatic light with the photon energy Eₚₕ either equal to Eₒₚₜ, or slightly larger (to match the spectral response maximum) would greatly increase the observed efficiency.

FIG. 4 shows the quantum efficiency (QE) curve of a typical poly-crystalline silicon solar cell. Immediate inspection of the data reveals that the solar cell is most sensitive at a wavelength range between about 550 nm to about 850 nm. Below about 500 nm, the quantum efficiency drops off noticeably. In operation, a phosphor-containing material acting as a wavelength-converter is placed adjacent to a solar or photovoltaic cell, the phosphor-containing material capable of absorbing solar irradiation at wavelengths 500 nm and below. Roughly speaking, this comprises blue light down (in wavelength) to the ultraviolet. The phosphor then emits light as photoluminescence from about 550 to about 850 nm, the region where the polycrystalline silicon cells are the most sensitive.

With use of the present embodiments, the overall efficiency in converting solar energy to electrical energy is greatly enhanced, since the down-converted light (one may even say, “conditioned light”) generated by the phosphor-containing material is more effectively absorbed by the silicon-based photovoltaic devices. The principle works similarly for both single crystal and polysilicon photovoltaic cells. The photovoltaic cells generate more electricity than they would have without the phosphor-containing wavelength-converter, a clearly advantageous situation.

### Phosphors as Wavelength Converters

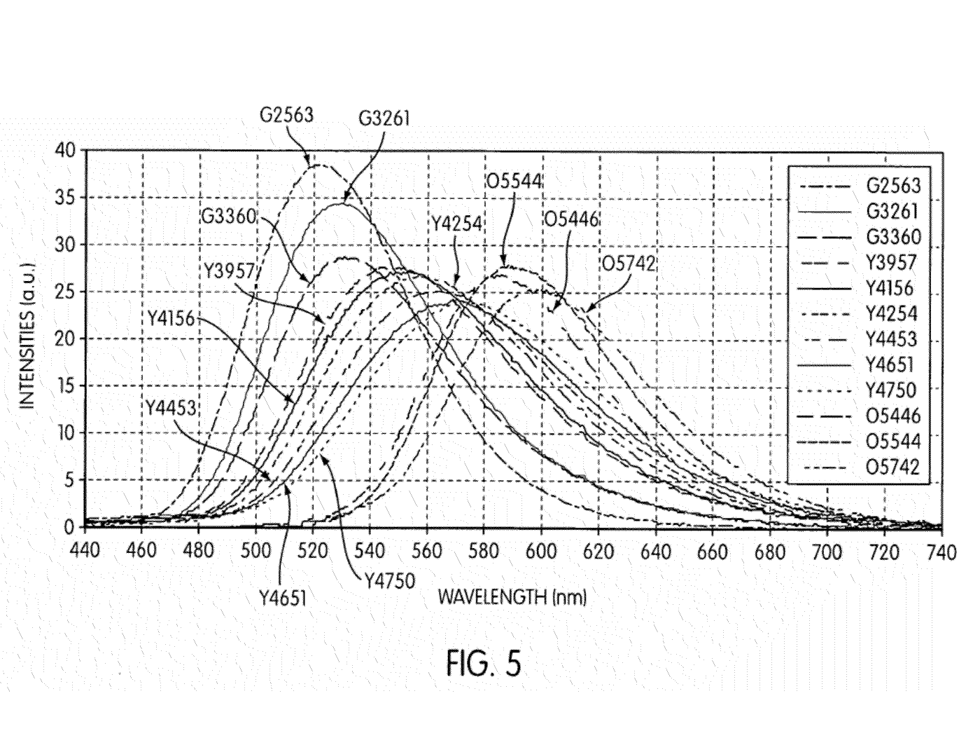

FIG. 5 shows the emission spectra of a variety of exemplary silicate-based phosphor materials emitting in a range of colors from green to red. Being inorganic materials, phosphors have excellent thermal stability and, do not demonstrate the susceptibility to UV degradation exhibited by their organic counterparts. This makes phosphor-containing materials as wavelength converters suitable to solar applications in both terrestrial and space environments, where the ambient temperatures can fluctuate dramatically.

The compositions of the phosphors shown in FIG. 5 are:

G2563: Sr_{0.925}Ba_{1.025}Mg_{0.05}Eu_{0.06}Si_{1.03}O₄Cl_{0.12}

Y4156: Sr_{1.40}Ba_{0.55}Mg_{0.05}Eu_{0.06}Si_{1.03}O₄Cl_{0.12}

Y4453: Sr_{1.6}Ba_{0.35}Mg_{0.05}Eu_{0.06}Si_{1.03}O₄Cl_{0.12}

Y4651: Sr_{1.725}Ba_{0.225}Mg_{0.05}Eu_{0.06}Si_{1.03}O₄Cl_{0.12}

Y4750: Sr_{1.725}Ba_{0.15}Mg_{0.05}Eu_{0.06}Si_{1.03}O₄Cl_{0.12}

O5446: Sr₃Eu_{0.06}Si_{1.02}O₅F_{0.18}

O5544: Sr_{2.94}Ba_{0.06}Eu_{0.06}Si_{1.02}O₅F_{0.18}

O5742: (Sr_{0.9}Ba_{0.1})_{2.76}Eu_{0.06}Si_{1.02}O₅F_{0.18.}

According to the present embodiments, a relatively straightforward way to practice an embodiment of the present invention is simply to coat a solar cell with a phosphor, phosphor blend, phosphor-containing composition, The phosphor may be contained within a transparent layer, and the phosphor may be applied either directly on the absorbing surface of the solar cell, or maintained in some manner adjacent to that surface. Coating a solar cell with a phosphor in some configuration will advantageously increase the energy conversion efficiency of an electricity generating device.

Phosphors are crystalline materials doped with rare-earth elements. The emission wavelength of the phosphor is tuned by choosing an appropriate doping species in conjunction with a particular host material; the two work in concert as a result of electron-phonon (phonons are quantized lattice vibrations) interactions associated with the local crystal field around the dopant and within the crystalline matrix. The advantage of using a phosphor over prior art luminescent materials such as organic dyes is that phosphors have a brighter emission, better chemical stability, and higher quantum efficiency. Phosphors are more robust and reliable materials than are organic dyes when used as spectral shifters.

By choosing a phosphor with an appropriate absorption range, one capable of absorbing substantially all the light having a wavelength smaller (photon energy larger) than its absorption edge, the phosphor functions as a superior spectral shifter. The phosphor coated on the solar cell absorbs this higher energy radiation (shorter wavelength light), and re-emits photons having a longer wavelength, thus providing “converted light” to the solar cell that is now matched to its spectral response maximum. It is by this mechanism that the conversion efficiency of the solar cell increases.

The advantages of the present embodiments are many. The phosphor can be applied to existing solar cell technologies with little or no modification to the solar cell design. Optimization of a phosphor spectral shifter can be done independently of the solar cell.

### Nano-Particle Containing Materials as Wavelength Converters

Over the past decade, nano-particles have been the subject of enormous interest. These materials possess sizes on the order of a billionth of a meter (10⁻⁹ m). They have at least one dimension being comparable to or smaller than 100 nm. Nano-particles are of great scientific and technological interests as they act effectively as a bridge between materials in their bulk forms, and molecular structures that make up those materials.

The electronic and optical properties of nanometer sized particles are often substantially different from those of the same materials in their bulk forms. For example, a blue-shift of the fundamental absorption edge is observed when the diameter of a nano-particle is decreased below a certain value (less than about 100 nm). The energy shift is a result of quantum confinement of the photo-excited carriers in the small particle. In essence, a plethora of applications have been created because of the ability to fine tune the optoelectronic properties by varying the size of the particles.

Nano-particles are ideal materials for applications of thin film coatings. They yield uniform and transparent layers on substrate surfaces. Because nano-particles have dimensions smaller than the wavelength of visible light, light scattering effects in the visible spectral range are minimized. Interaction of light with nano-particles can be well described by Mie theory. This theory explains that the scattering and absorption of the particles is a function of their diameters and shapes, as well as the wavelength of the incident light. The theory states that when light impinges on a thin film coating of nano-particles, the intensities of the incident and the scattered lights, together with the light absorbed by the thin film, follow Lambert-Beer's law:

ln(Iₚ/I)=τl; τ=εc,

where Iₚ is the intensity of the incident light; I is the intensity of the light passing through the thin film; τ is the turbidity; l is the thickness of the thin film; c is the concentration of the particles in solution that is composed of the thin film; and ε=τ/c is the specific turbidity of extinction coefficient. The calculation of the extinction coefficient for spheres has been explicitly derived by Mie. Starting with Maxwell's equations, Mie developed the extinction efficiency Qₑₓₜ as a function of the size parameter πd/λ (d=diameter, λ=wavelength) and the refractive indices of the solvent n₀ and spherical particles n₁. For the extinction cross section Cₑₓₜ (total light energy absorbed and scattered by one sphere), the following relationship may be expressed:

Cₑₓₜ=Qₑₓₜπd²/4.

The turbidity τ is then defined as

τ=NCₑₓₜ,

with N being the number of particles per unit volume. By simple conversion,

π/c=ε=3Qₑₓₜ/(2ρd),

with ρ being the density of the particles. The values of specific turbidity τ/c as a function of the reduced size parameter πd/λ and n₁/n₀ have been calculated in the literature. See, for example, J. Serb. Chem. Soc. 70(3) 364 (2005).

Assuming the size of a nano-particle is 100 nm and the wavelength of incident light is 420 nm, one could derive πd/λ=0.75 from the equations discussed above. In solar photovoltaics (PV) application, for instance, the scattering loss should be below 5 percent. The consequences of this are that:

ln(Iₚ/I)=ln(1/0.95)≈0.05=τl.

If one assumes (a reasonable assumption) that the thickness of the thin film is 20 μm and c is 2 g/cm³, then

τ/c=ln(Iₚ/I)/(lc)=0.05/(20*10⁻⁴*2)=12.5*10⁻³ cm²/g.

An exemplary binder is a silicone gel. With n₀=1.45, n₁=1.8 (for most oxide phosphors), n₁/n₀=1.24. The above reference teaches that the value of τ/c corresponding to πd/λ=0.75 at n₁/n₀=1.25 is not higher than 10*10⁻³ cm²/g, which is smaller than the acceptance level of 12.5*10⁻³ cm²/g. The specific turbidity of the coating is less than what is given with a scattering loss of 5 percent, and therefore, the actual scattering loss of the coating is less than 5 percent.

This result shows theoretically that the scattering loss can be minimized below 5 percent in a solar or photovoltaic application. Precise control of particle size and uniformity allow for a transparent and uniform coating on the solar cell substrate. This transparent layer allows visible light to pass through with very minimal scattering and little or no absorption. Radiation in the ultra-violet portion of the spectrum is absorbed by the nano-phosphor layer, and wavelength-converted downwards to visible light that may be effectively utilized by the solar cell. Therefore, such a coating with a nano-phosphor containing layer can enhance overall performance of the solar cell by utilizing the ultraviolet radiation in the solar spectrum in addition to the lower energy visible portion.

### Synthesis of Nano-Particles

According to the present embodiments, preparing the materials at a nanosize scale makes use of wet chemical methods such as liquid phase precipitation and sol-gel formations. Hybrid chemicals/physical methods including spray pyrolysis and flame hydrolysis can also be used. Additionally, physical methods such as mechanical size reduction and physical vapor phase deposition may be used to fabricate nano-particles of the present phosphors comprising a wavelength-converter.

In addition to the silicate-based phosphors belonging to the present inventors, a technique has been developed to fabricate YAG:Ce nano-particles using a co-precipitation method. In this method, desired amounts of Y(NO₃)₃, Al(NO₃)₃ and Ce(NO₃)₃ are dissolved in de-ionized water; the solution is then added drop-wise to ammonia and the resulting mixture stirred for about one hour to induce co-precipitation. The precipitant is then filtered out and thoroughly washed with de-ionized water. After drying, the white powder is sintered at 1100° C. for about six hours in a reducing atmosphere. The particle size of the YAG:Ce particles is about 40 nm and the emission light output excited by 450 nm is about 60 percent of a commercial YAG:Ce phosphor.

### Demonstration of a Phosphor-Based Wavelength-Converter

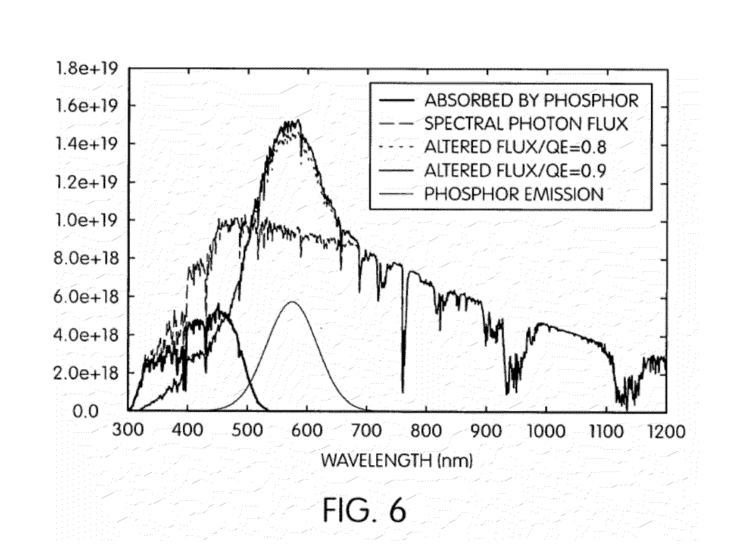

A demonstration of the present embodiments is shown in FIG. 6, which shows the results of using a 565 nm phosphor as a wavelength-converter (synonymous with the term spectral shifter). This phosphor has an absorption edge at about 535 nm, an emission maximum around 565 nm, and an emission full width at half maximum of about 380 meV. The absorption of AM1.5G solar irradiance in short wavelengths was calculated based on the experimentally obtained excitation spectrum from the phosphor. Using an external quantum efficiency around 80 to 90 percent, the phosphor is seen to alter the spectral distribution of the photon flux from the sunlight by shifting the portion of the photon flux from the short wavelength range of the solar spectrum to a longer wavelength range; this additional photon flux is superimposed on the longer wavelength portion of the solar spectrum which is not absorbed by the phosphor.

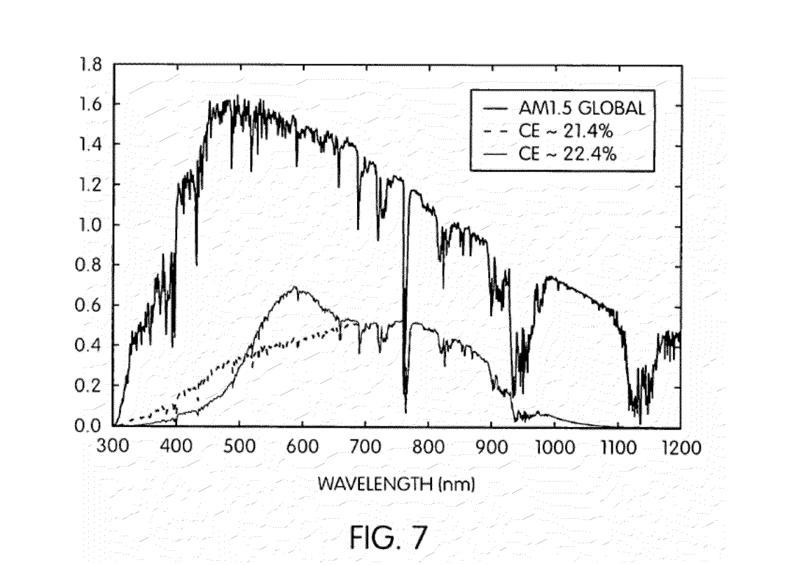

FIG. 7 is a graph of spectral irradiance (in Wm⁻² nm⁻¹) versus wavelength for a solar cell having a 565 nm phosphor-based wavelength converter under AM1.5G solar irradiance. The spectral response of this solar cell is the same as that shown in FIG. 2. The spectral irradiance provided to a solar cell lacking the phosphor spectral shifter is shown for comparison in FIG. 7, as well as the spectral irradiance at AM1.5G sun.

The results in FIG. 7 show that a greater than 1 percent increase in the conversion efficiency is provided by the phosphor-based wavelength-converter. It is noted that the phosphor used in this case has not been optimized to match the spectral response maximum of the silicon solar cell shown in FIG. 1. A much larger increase of conversion efficiency is contemplated when a phosphor having an emission peak that better matches the 800 nm maximum of the silicon solar cell is used.

What is claimed is:

1. A solar wavelength-converter for converting higher energy shorter wavelength solar light to lower energy longer wavelength light, the wavelength-converter comprising: a transparent matrix having particles of at least one inorganic phosphor embedded in it wherein the at least one phosphor is configured to absorb solar radiation of wavelengths between about 300 nm and about 480 nm and convert it to light with a wavelength greater than about 500 nm.

2. The solar wavelength converter of claim 1, wherein the at least one phosphor comprises particles of a size that is substantially transparent to solar radiation having a wavelength greater than about 460 nm.

3. The solar wavelength converter of claim 2, wherein at least some of the at least one phosphor particles have a dimension of about 100 nm or less.

4. The solar wavelength converter of claim 1, wherein the transparent matrix comprises a polymeric material.

5. The solar wavelength-converter of claim 4, wherein the transparent matrix comprises a silicone gel.

6. The solar wavelength-converter of claim 1, wherein the at least one phosphor is selected from the group consisting of: a YAG:Ce phosphor; a silicate-based phosphor of a form M₂Sia₄:Eu²⁺; a silicate-based phosphor of a form M₃SiO₅:Eu₂₊, where M is a divalent cation in the silicate-based phosphors; and combinations thereof.

7. The solar wavelength-converter of claim 1, wherein the at least one phosphor has a composition (Ba_{1-x-y}SrₓMg_{y})_{z}Si_{2+z}:Eu²⁺, where
0≦x≦1;
0≦y≦1; and
z is any value between 1.5 and 2.5, both inclusive.

8. The solar wavelength-converter of claim 1, wherein the at least one phosphor has a composition (Ba_{1-x-y}SrₓMg_{y})_{z}Si_{2+z}:Eu²⁺, where
0≦x≦1;
0≦y≦1; and
z is any value between 2.5 and 3.5, both inclusive.

9. The solar wavelength-converter of claim 1, wherein the at least one phosphor is selected from the group consisting of:
Sr_{0.925}Ba_{1.025}Mg_{0.05}Eu_{0.06}Si_{1.03}O₄Cl_{0.12};
Sr_{1.40}Ba_{0.55}Mg_{0.05}Eu_{0.06}Si_{1.03}O₄Cl_{0.12};
Sr_{1.6}Ba_{0.35}Mg_{0.05}Eu_{0.06}Si_{1.03}O₄Cl_{0.12};
Sr_{1.725}Ba_{0.225}Mg_{0.05}Eu_{0.06}Si_{1.03}O₄Cl_{0.12};
Sr_{1.725}Ba_{0.15}Mg_{0.05}Eu_{0.06}Si_{1.03}O₄Cl_{0.12};
Sr₃Eu_{0.06}Si_{1.02}O₅F_{0.18};
Sr_{2.94}Ba_{0.06}Eu_{0.06}Si_{1.02}O₅F_{0.18};
(Sr_{0.9}Ba_{0.1})_{2.76}Eu_{0.06}Si_{1.02}O₅F_{0.18}; and combinations thereof.

10. A solar wavelength-converter for converting higher energy shorter wavelength solar light to lower energy longer wavelength light, the wavelength-converter comprising: a transparent matrix having particles of at least one inorganic phosphor embedded in it wherein the at least one phosphor is selected from the group consisting of: a YAG:Ce phosphor; a silicate-based phosphor of a form M₂Sia₄:Eu²⁺; a silicate-based phosphor of a form M₃SiO₅:Eu₂₊, where M is a divalent cation in the silicate-based phosphors; and combinations thereof.

11. The solar wavelength-converter of claim 10, wherein the at least one phosphor has a composition (Ba_{1-x-y}SrₓMg_{y})_{z}SiO_{2+z}:Eu²⁺, where
0≦x≦1;
0≦y≦1; and
z is any value between 1.5 and 2.5, both inclusive.

12. The solar wavelength-converter of claim 10, wherein the at least one phosphor has a composition (Ba_{1-x-y}SrₓMg_{y})_{z}Si_{2+z}:Eu²⁺, where
0≦x≦1;
0≦y≦1; and
z is any value between 2.5 and 3.5, both inclusive.

13. The solar wavelength-converter of claim 10, wherein the at least one phosphor has a composition (Ba_{1-x-y}SrₓMg_{y})_{z}SiO_{2+z}:Euₓ²⁺, where
0.001≦x≦0.2;
0.001≦y≦0.2; and
z is any value between 1.5 and 2.5, inclusive.

14. The solar wavelength-converter of claim 10, wherein the phosphor is selected from the group consisting of:
Sr_{0.925}Ba_{1.025}Mg_{0.05}Eu_{0.06}Si_{1.03}O₄Cl_{0.12};
Sr_{1.40}Ba_{0.55}Mg_{0.05}Eu_{0.06}Si_{1.03}O₄Cl_{0.12};
Sr_{1.6}Ba_{0.35}Mg_{0.05}Eu_{0.06}Si_{1.03}O₄Cl_{0.12};
Sr_{1.725}Ba_{0.225}Mg_{0.05}Eu_{0.06}Si_{1.03}O₄Cl_{0.12};
Sr_{1.725}Ba_{0.15}Mg_{0.05}Eu_{0.06}Si_{1.03}O₄Cl_{0.12};
Sr₃Eu_{0.06}Si_{1.02}O₅F_{0.18};
Sr_{2.94}Ba_{0.06}Eu_{0.06}Si_{1.02}O₅F_{0.18};
(Sr_{0.9}Ba_{0.1})_{2.76}Eu_{0.06}Si_{1.02}O₅F_{0.18}; and combinations thereof.

15. The solar wavelength-converter of claim 10, wherein the at least one phosphor is configured to absorb light of wavelengths between about 300 nm and about 480 nm and convert it to light with a wavelength greater than about 500 nm.

16. The solar wavelength converter of claim 10, wherein the at least one phosphor comprises particles of a size that is substantially transparent to solar radiation having a wavelength greater than about 460 nm.

17. The solar wavelength-converter of claim 16, wherein at least some of the at least one phosphor particles have a dimension of about 100 nm or less.

18. The solar wavelength-converter of claim 10, wherein the transparent matrix comprises a polymeric material.

19. The solar wavelength-converter of claim 10, wherein the transparent matrix comprises a silicone gel.

20. A photovoltaic device with enhanced conversion efficiency, comprising:
a solar cell for converting solar radiation into electrical energy; and
a wavelength-converter of claim 1 or claim 10, the wavelength-converter being configured to emit converted light with a wavelength greater than about 500 nm onto the solar cell.
